(19) United States
(12) Patent Application Publication
(10) Pub. No.: US 2006/0162157 A1
(43) Pub. Date: Jul. 27, 2006

(54) Economical high-frequency package

(76) Inventors: Gernot Schimetta, Munich (DE); Karl Weidner, Munich (DE); Joerg Zapf, Munich (DE)

Correspondence Address: STAAS & HALSEY LLP, SUITE 700, 1201 NEW YORK AVENUE, N.W., WASHINGTON, DC, 20005, US

(21) Appl. No.: 10/527,961

(22) PCT Filed: Jun. 29, 2004
(86) PCT No.: PCT/EP04/51282

§ 371 Date: Mar. 15, 2005

(30) Foreign Application Priority Data
Jun. 30, 2003 (DE) 103 29 329.9

(51) Int. Cl. H05K 3/10

(52) U.S. Cl. 29/846; 29/840; 174/250

(57) ABSTRACT

A component is connected to a circuit carrier via contacts which place the component at a distance from the circuit carrier. A foil is applied to the component and the circuit carrier so that it lies close to the surface of the circuit carrier on which the component is located and to the sides of the component not facing the circuit carrier. After being applied to the component and the circuit carrier the film is provided with a metal coating.

### CROSS REFERENCE TO RELATED APPLICATIONS

This application is based on and hereby claims priority to German Application No. 103 29 329.9 filed on Jun. 30, 2003, the contents of which are hereby incorporated by reference.

### BACKGROUND OF THE INVENTION

Known hermetically-sealed high-frequency packages for modules predominantly consist of milled metal housings which are gold plated and subsequently sealed with a soldered-on metal cover. Hermetically-sealed single-chip ceramic housings, as used for SAW chips for example, are also cost-intensive and less suitable for chips with high-power dissipation.

Normal HF metal housings, as are often used for modules when a hermetic seal is not required but good screening is, are very expensive, very large and not hermetically sealed.

Also expensive are HF module housings based on the very latest LTCC technology. In such housings the ceramic is only used for routing the lines while the cover is soldered on.

Typical SAW filter packages based on HTCC technology are seam-welded and can be used up to around 5 GHz for components without high power dissipation. The cover welding is however labor-intensive and the housings can only be used for a restricted frequency range.

Current, hermetically-sealed CSP housings are also expensive on account of their soldered-on Au—Sn covers to be used in the high-frequency range.

From DE 100 41 770 A1 a substrate is known with a first dielectric layer, a high-frequency structure layer which contains a high-frequency distribution network and at least one low-frequency structure layer. A module formed with this also includes a cover.

From WO 97/45955 A1, WO 99/43084 A1, DE 195 48 048 A1 and DE 198 18 824 A1 electronic components located on circuit carriers are known which are enclosed by covers, especially in the form of foils. Metal foils used for such purposes have proved to be very difficult to handle and often not durable over long periods.

### SUMMARY OF THE INVENTION

An underlying object of the invention is to specify a low-cost method for manufacturing a high-frequency package.

Accordingly a circuit carrier is connected to a component via contacts which place the component at a distance from the circuit carrier so that voids are formed between the circuit carrier and the contacts. A foil is applied to the component and the circuit carrier so that it lies close to the surface of the circuit carrier on which the component is located and to the sides of the component not facing the circuit carrier. After being applied to the component and the circuit carrier the film is provided with a metal coating.

A solder bump is placed on the side of the circuit carrier on which the component is placed. This solder bump projects beyond the component, in that it is higher than the component when seen from the circuit carrier. In this way the package consisting of circuit carrier, component, foil and metallization of the foil can be electrically connected via the solder bump on the side on which the component is arranged on the circuit carrier to a further circuit carrier for example.

Preferably the metallization is applied by sputtering or vapor deposition and subsequently electrically strengthened.

In the foil a window can be opened up on the side of the component facing away from the circuit carrier via which contact can be made with the component. If the window is opened up before the metallization of the foil, the contacting can be undertaken at the same time as the metallization.

The component may in particular be an active component, a high-frequency component and/or a very-high-frequency component.

In addition to the component, one or more further passive components can be arranged on the circuit carrier. The passive components are preferably arranged on the opposite side of the circuit carrier to the component.

### BRIEF DESCRIPTION OF THE DRAWINGS

These and other objects and advantages of the present invention will become more apparent and more readily appreciated from the following description of exemplary embodiments with reference to the accompanying drawings of which:

FIG. 1 is partial cross section of a circuit carrier equipped with components on one side, with screen-printed solder bumps on the back of the circuit carrier;

FIG. 2 is partial cross section of a circuit carrier equipped with components on both sides with solder balls or solder bumps placed on the front of the circuit carrier and surface-mounted passive components on the back of the circuit carrier.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

The packages are processed in the wafer and this can typically be done as follows. In accordance with the universality of the invention numerous changes in the process chain are possible.

Components 1 in the form of chips are bumped and for printed contacts 2 in the form of solder bumps these are encapsulated. Alternatively a circuit carrier 3 can also be bumped.

The components 1 are separated, turned around with the contacts 2, dipped in flux and placed on the connection pads of the circuit carrier 3 designed in ceramic for example. This produces voids 4 between the component 1, the contacts 2 and the circuit carrier 3.

Subsequently a foil 5 is laminated over the entire surface of the components 1 and removed at contacting points as well as at the edges of the modules (saw tracks)by a laser for example.

The foil is provided by coating the entire surface typically by Cu sputtering with a metallization 6, which is electrically strengthened if necessary.

Preferably one or more frames 12 run on the circuit carrier 3 in the form of metallization on the ceramic, at which the foil 5 has been removed. Here the metal screening stretched over the components 1 in the form of the metallization 6 is connected directly to the circuit carrier 3. This forms a hermetically-sealed package.

Since the contacts 2 in the form of bumps in the voids 4 are surrounded by air, meaning that the dielectric constant between the contacts 2 is around 1, use in up to the highest-frequency technology is possible. Components with high power dissipation, for example GaAs chips, can be reworked before being placed on the carrier. A window 7 cut out by a laser or similar in the foil 5 on the side of the components 1 facing away from the circuit carrier 3 allows the copper metallization 6 to be contacted directly with the component surface. Thus the foil 5 does not prevent heat being dissipated. In the same way a ground connection of the component rear side can be implemented.

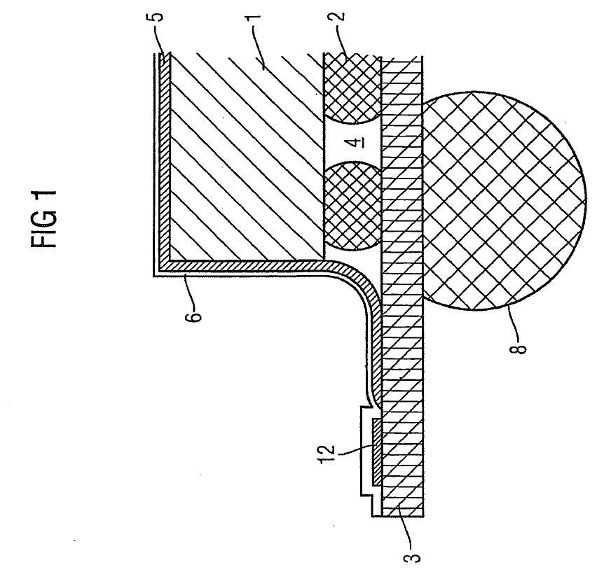

In the embodiment in accordance with FIG. 1 a contact element 8 in the form of a solder bump is arranged on the opposite side of the circuit carrier 3 from the component 1.

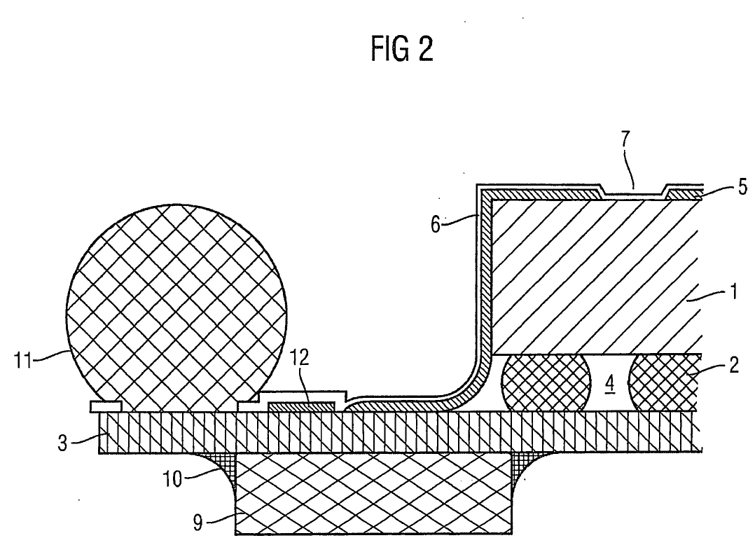

In the embodiment in accordance with FIG. 2 a passive component 9 is arranged on the opposite side of the circuit carrier 3 to the component 1 and is soldered on with solder 10.

Furthermore, on the side of the circuit carrier 3 on which the component 1 is located a contact element 11 in the form of a solder bump is arranged which projects higher above the surface of the circuit carrier 3 than the component 1 with the contacts 2.

The variants shown only represent preferred embodiments. Typical components which might be used are Si or GaAs chips, also in mixed configurations. Trials have been conducted using LTCC ceramics as substrates for the circuit carrier, but other ceramics, such as HTCC or Al₂O₃, or organic substrates such as FR5, with the lowest possible coefficients of expansion are also conceivable. The embodiment shown in FIG. 1 can for example be enabled for pick and place by a casting compound which makes lower-cost component placement possible.

If chips have to be contacted by wire bonding, this can either be arranged on the back or also accommodated with a protective cover under the screening foil 5.

All embodiments of the invention have the following unique advantages:
Suitable for the highest frequencies (>20 GHz), since no underfill (ε=1 between the bumps), short, constant-length signal delay times (flip-chip instead of wire bonds),
Hermetic seal and ESD screening at very low cost through fabrication in the wafer,
Heat dissipation of components possible, for example by application of heat sinks,
Universality: Different components and circuit carrier substrates can be combined with HTCC and LTCC technology, SMD components can be mounted on the back of the circuit carrier for example,
Easily adaptable to different package types.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-9. (canceled)

10. A method, comprising:
connecting a circuit carrier to a component via contacts which place the component at a distance from the circuit carrier;
applying a foil to the component and the circuit carrier;
metallizing the foil; and
placing a solder bump as a contact element on a first side of the circuit carrier on which the component is arranged, the solder bump projecting beyond the component.

11. A method according to claim 10, wherein said metallizing of the foil includes electrically strengthening metallization of the foil.

12. A method according to claim 11, further comprising opening a window in the foil on a side of the component facing away from the circuit carrier.

13. A method according to claim 12, wherein the component is a high-frequency component, especially an very-high frequency component.

14. A method according to claim 13, further comprising mounting a passive component on the circuit carrier.

15. A method according to claim 14, wherein said mounting of the passive component occurs on a second side opposite the first side of the circuit carrier on which the high-frequency component is connected.

16. A high frequency package, manufactured in accordance with claim 10.

17. A high frequency package, manufactured in accordance with claim 11.

18. A high frequency package, manufactured in accordance with claim 12.

19. A high frequency package, manufactured in accordance with claim 13.

20. A high frequency package, manufactured in accordance with claim 14.

21. A high frequency package, manufactured in accordance with claim 15.
